(19) United States
(12) Patent Application Publication
(10) Pub. No.: US 2025/0255107 A1
(43) Pub. Date: Aug. 7, 2025

(54) DISPLAY DEVICE AND METHOD FOR MANUFACTURING THE SAME

(71) Applicant: Samsung Display Co., LTD., Yongin-si (KR)

(72) Inventor: Hyun Eok SHIN, Yongin-si (KR)

(73) Assignee: Samsung Display Co., LTD., Yongin-si (KR)

(21) Appl. No.: 18/895,702

(22) Filed: Sep. 25, 2024

(30) Foreign Application Priority Data
Feb. 6, 2024 (KR) 10-2024-0017882

(51) Int. Cl. H10K 59/122; H10K 59/12

(52) U.S. Cl. CPC H10K 59/122; H10K 59/1201

(57) ABSTRACT

A display device may include a substrate including an emission area and a non-emission area, a bank structure positioned on the emission area of the substrate and having an undercut shape, a pixel electrode positioned on the bank structure, a first light emitting layer positioned on the pixel electrode, a first cathode electrode positioned on the first light emitting layer, a first capping layer positioned on the first cathode electrode, a connection electrode positioned on the first capping layer, a pixel defining layer positioned on the non-emission area of the substrate and defining a first opening, an inorganic layer positioned on the pixel defining layer and defining a second opening, and an organic layer positioned on the inorganic layer.

### CROSS-REFERENCE TO RELATED APPLICATIONS

This application claims priority under 35 U.S.C. 119 from Korean Patent Application No. 10-2024-0017882 filed on Feb. 6, 2024 in the Korean Intellectual Property Office, the entire contents of which are incorporated herein by reference.

### BACKGROUND

### 1. Technical Field

The disclosure relates to a display device and a method for manufacturing the same.

### 2. Description of the Related Art

As the information society develops, the demand for display devices for displaying images has increased and diversified. For example, display devices have been applied to various electronic devices such as smartphones, digital cameras, laptop computers, navigation devices, and smart televisions. The display devices may be flat panel display devices such as liquid crystal display devices, field emission display devices, or organic light emitting display devices. Among such flat panel display devices, a light emitting display device may display an image without a backlight portion providing light to a display panel because each of pixels of the display panel may include light emitting elements that may emit light by themselves.

Recently, the display devices have been applied to glasses-type devices for providing virtual reality and augmented reality. The display device may be implemented in a very small size of 2 inches or less in order to be applied to the glasses-type device, but should have a high pixel integration degree in order to be implemented with high resolution. For example, the display device may have a high pixel integration degree of 1000 pixels per inch (PPI) or more.

In case that the display device is implemented in the very small size but has the high pixel integration degree as described above, sizes of emission areas where light emitting elements are disposed are reduced, and thus, it is difficult to implement light emitting elements separated from each other for each emission area through a mask process.

### SUMMARY

Aspects of the disclosure provide a display device having high pixel integration degree and a method of manufacturing a display device having an ease of manufacturing.

However, aspects of the disclosure are not restricted to those set forth herein. The above and other aspects of the disclosure will become more apparent to one of ordinary skill in the art to which the disclosure pertains by referencing the detailed description of the disclosure given below.

Detailed contents of other embodiments are described in a detailed description and are illustrated in the drawings.

According to an aspect of the disclosure, a display device may include a substrate including an emission area and a non-emission area; a bank structure positioned on the emission area of the substrate and having an undercut shape; a pixel electrode positioned on the bank structure; a first light emitting layer positioned on the pixel electrode; a first cathode electrode positioned on the first light emitting layer; a first capping layer positioned on the first cathode electrode; a connection electrode positioned on the first capping layer; a pixel defining layer positioned on the non-emission area of the substrate and defining a first opening; an inorganic layer positioned on the pixel defining layer and defining a second opening; and an organic layer positioned on the inorganic layer.

In an embodiment, the bank structure may include a first bank layer; and a second bank layer positioned on the first bank layer and including a tip protruding toward the non-emission area more than a side surface of the first bank layer.

In an embodiment, the first bank layer and the second bank layer may include different inorganic insulating materials.

In an embodiment, a height of the first bank layer in a vertical direction of the substrate may be higher than a height of the second bank layer.

In an embodiment, the side surface of the first bank layer may be entirely covered by the pixel defining layer.

In an embodiment, the second bank layer may include a first surface facing the pixel electrode, a second surface facing the first bank layer, and a side surface connecting the first surface and the second surface.

In an embodiment, the first surface and the side surface of the second bank layer may be in contact with the pixel electrode, and the second surface may be in contact with the pixel defining layer.

In an embodiment, the display device may further comprise a residual pattern positioned on the non-emission area of the substrate, wherein the residual pattern and the pixel electrode may include a same material, the residual pattern may be spaced apart from the pixel electrode.

In an embodiment, the pixel defining layer entirely may cover the residual pattern.

In an embodiment, the display device may further comprise a second light emitting layer spaced apart from the first light emitting layer in a direction parallel to the substrate with the organic layer disposed between the first light emitting layer and the second light emitting layer; a second cathode electrode positioned on the second light emitting layer; and a second capping layer positioned on the second cathode electrode, wherein the first cathode electrode and the second cathode electrode may be spaced apart from each other and the first capping layer and the second capping layer may be spaced apart from each other.

In an embodiment, the first capping layer may be electrically connected to the first cathode electrode, and the second capping layer may be electrically connected to the second cathode electrode.

In an embodiment, the connection electrode may include a first portion in contact with the first capping layer; a second portion in contact with the second capping layer; and a third portion in contact with the organic layer.

In an embodiment, the first portion and the second portion may be spaced apart from each other with the third portion disposed between the first portion and the second portion.

In an embodiment, the inorganic layer may include a first inorganic layer surrounding an edge of the first capping layer; and a second inorganic layer surrounding an edge of the second capping layer, wherein the first inorganic layer and the second inorganic layer may be spaced apart from each other with the organic layer disposed between the first inorganic layer and the second inorganic layer.

In an embodiment, in plan view, the first opening may be entirely surrounded by the second opening.

According to an aspect of the disclosure, a method of manufacturing a display device may include forming a first bank layer on a substrate and forming a second bank layer on the first bank layer; etching a portion of the first bank layer and a portion of the second bank layer so that the second bank layer may include a tip protruding more than a side surface of the first bank layer; forming a pixel electrode on the second bank layer and a residual pattern on the substrate; forming a pixel defining layer surrounding an edge of the pixel electrode and covering the residual pattern; forming a light emitting layer, a cathode electrode, and a capping layer on the pixel electrode; and forming a connection electrode on the capping layer.

In an embodiment, in forming the pixel electrode, the pixel electrode may not include a separate etching process since the second bank layer may include a tip.

In an embodiment, in the forming the cathode electrode and the capping layer, the cathode electrode may entirely cover the light emitting layer, and the capping layer entirely covers the cathode electrode.

In an embodiment, a method of manufacturing a display device may further comprise forming an inorganic layer and an organic layer after the forming of the capping layer and before the forming of the connection electrode, wherein in forming the inorganic layer, the inorganic layer may surround an edge of the capping layer and may cover a portion of the residual pattern.

In an embodiment, in the forming the connection electrode, the connection electrode may extend to the capping layer, the inorganic layer, and the organic layer, and the cathode electrode may be electrically connected to the connection electrode through the capping layer.

With a display device and a method for manufacturing the same according to an embodiment, the display device may include a bank structure having undercut structures under pixel electrodes, such that a gap of multiple pixel electrodes may be minimized and may have case of manufacturing of a light emitting element. Accordingly, according to a display device and a method of manufacturing the same according to an embodiment, a high-resolution display device having an ease of manufacturing may be provided.

The effects of the disclosure are not limited to the aforementioned effects, and various other effects are included in the specification.

### BRIEF DESCRIPTION OF THE DRAWINGS

The above and other aspects and features of the disclosure will become more apparent by describing in detail embodiments thereof with reference to the attached drawings, in which:

FIG. 1 is a perspective view illustrating a head mounted electronic device according to an embodiment;

FIG. 2 is an exploded perspective view of the head mounted electronic device of FIG. 1;

FIG. 3 is a perspective view illustrating a head mounted electronic device according to an embodiment;

FIG. 4 is an exploded perspective view illustrating a display device according to an embodiment;

FIG. 5 is an enlarged plan view of a display area of a display panel of FIG. 4;

FIG. 6 is a schematic cross-sectional view of a display panel according to an embodiment taken along line X1-X1′ in FIG. 5;

FIG. 7 is an enlarged schematic cross-sectional view of a light emitting element layer and an encapsulation layer positioned to overlap a first emission area in FIG. 6;

FIG. 8 an enlarged schematic cross-sectional view of a light emitting element layer and an encapsulation layer positioned to overlap a non-emission area positioned between the first emission area and a second emission area;

FIG. 9 is a schematic cross-sectional view of a display panel according to an embodiment taken along line X3-X3′ in FIG. 5; and

FIGS. 10 to 23 are schematic cross-sectional views sequentially illustrating a manufacturing process of a light emitting element layer of a display panel according to an embodiment.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the disclosure. Therefore, unless otherwise specified, the features, components, modules, layers, films, panels, regions, and/or aspects, etc., (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may be different directions that are not perpendicular to one another.

For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc., may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, parts, and/or modules. Those skilled in the art will appreciate that these blocks, parts, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, parts, and/or modules being implemented by microprocessors or other similar hardware, they may be programmed and controlled using software (e.g., microcode) to perform various functions discussed herein and may optionally be driven by firmware and/or software. It is also contemplated that each block, part, and/or module may be implemented by dedicated hardware, or as a combination of dedicated hardware to perform some functions and a processor (e.g., one or more programmed microprocessors and associated circuitry) to perform other functions. Also, each block, part, and/or module of some embodiments may be physically separated into two or more interacting and discrete blocks, parts, and/or modules without departing from the scope of the inventive concepts. Further, the blocks, parts, and/or modules of some embodiments may be physically combined into more complex blocks, parts, and/or modules without departing from the scope of the inventive concepts.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

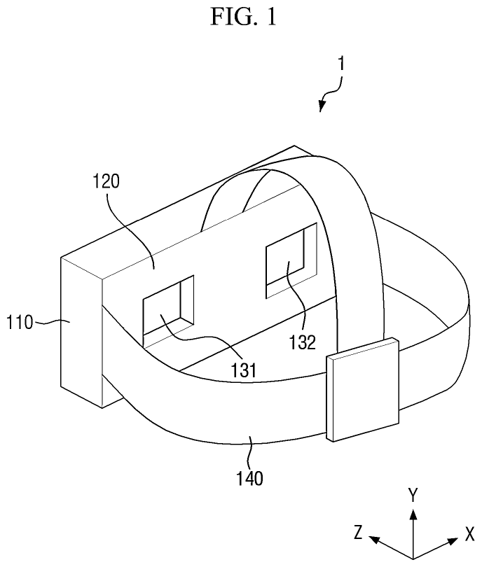

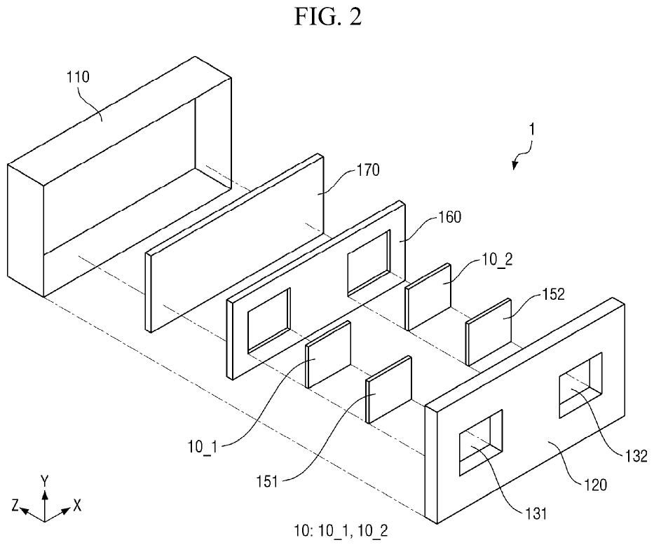

FIG. 1 is a perspective view illustrating a head mounted electronic device according to an embodiment. FIG. 2 is an exploded perspective view of the head mounted electronic device of FIG. 1.

Referring to FIGS. 1 and 2, a head mounted electronic device 1 according to an embodiment may include a display device 10, a display device housing portion 110, a housing portion cover 120, a first eyepiece 131, a second eyepiece 132, a head mounted band 140, a middle frame 160, a first optical member 151, a second optical member 152, and a control circuit board 170.

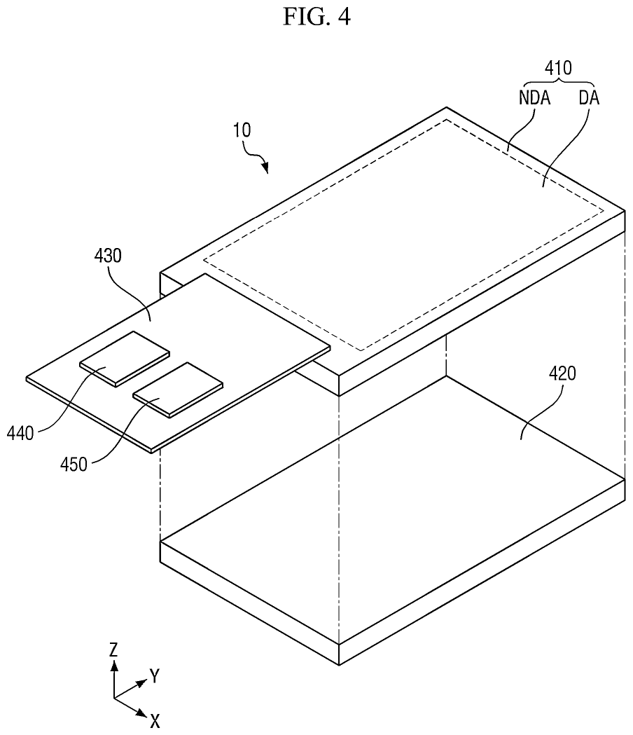

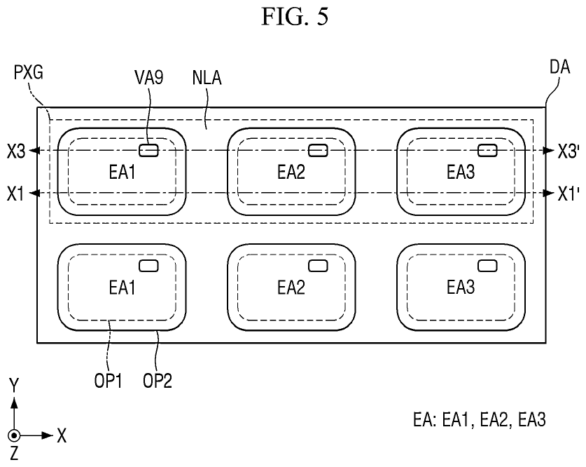

The display device 10 may include a first display device 10_1 and a second display device 10_2. The first display device 10_1 provides an image to a user's left eye, and the second display device 10_2 provides an image to a user's right eye. The display device 10 will be described in detail later with reference to FIGS. 4 and 5.

The first optical member 151 may be disposed between the first display device 10_1 and the first eyepiece 131, and the second optical member 152 may be disposed between the second display device 10_2 and the second eyepiece 132. Each of the first optical member 151 and the second optical member 152 may include at least one convex lens.

The middle frame 160 may be disposed between the first display device 10_1 and the control circuit board 170 and disposed between the second display device 10_2 and the control circuit board 170. The middle frame 160 may serve to support and fix the first display device 10_1, the second display device 10_2, and the control circuit board 170.

The control circuit board 170 may be disposed between the middle frame 160 and the display device housing portion 110. The control circuit board 170 may be electrically connected to the first display device 10_1 and the second display device 10_2 through a connector. The control circuit board 170 may convert an image source input from the outside into digital video data, and transmit the digital video data to the first display device 10_1 and the second display device 10_2 through the connector.

The control circuit board 170 may transmit digital video data corresponding to a left eye image optimized for the user's left eye to the first display device 10_1 and may transmit digital video data corresponding to a right eye image optimized for the user's right eye to the second display device 10_2. As another example, the control circuit board 170 may transmit the same digital video data to the first display device 10_1 and the second display device 10_2.

The display device housing portion 110 may serve to house the display device 10, the middle frame 160, the first optical member 151, the second optical member 152, and the control circuit board 170. The housing portion cover 120 may be disposed to cover an open surface of the display device housing portion 110. The housing portion cover 120 may include the first eyepiece 131 on which the user's left eye may be disposed and the second eyepiece 132 on which the user's right eye may be disposed. It has been illustrated in FIGS. 1 and 2 that the first eyepiece 131 and the second eyepiece 132 may be separately disposed, but an embodiment of the disclosure is not limited thereto. The first eyepiece 131 and the second eyepiece 132 may be merged as one eyepiece.

The first eyepiece 131 may be aligned with the first display device 10_1 and the first optical member 151, and the second eyepiece 132 may be aligned with the second display device 10_2 and the second optical member 152. Accordingly, a user may view an image of the first display device 10_1 magnified as a virtual image by the first optical member 151 through the first eyepiece 131, and may view an image of the second display device 10_2 magnified as a virtual image by the second optical member 152 through the second eyepiece 132.

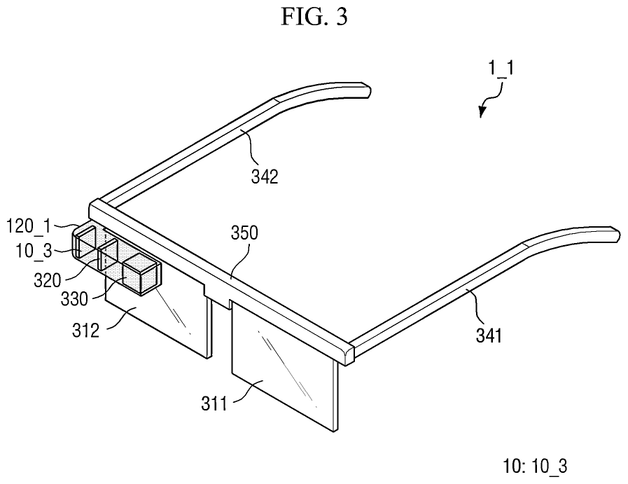

The head mounted band 140 serves to fix the display device housing portion 110 to a user's head so that the first eyepiece 131 and the second eyepiece 132 of the housing portion cover 120 may be maintained in a state in which they may be disposed on the user's left eye and right eye, respectively. In case that the display device housing portion 110 is implemented to have a light weight and a small size, the head mounted electronic device 1 may include an eyeglass frame as illustrated in FIG. 3 instead of the head mounted band 140.

The head mounted electronic device 1 may further include a battery for supplying power, an external memory slot for housing an external memory, an external connection port, and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a wireless fidelity (WiFi) module, or a Bluetooth module.

FIG. 3 is a perspective view illustrating a head mounted electronic device according to an embodiment.

Referring to FIG. 3, a head mounted electronic device 1_1 according to an embodiment may be a glasses-type electronic device in which a display device housing portion 120_1 may be implemented to have a light weight and a small size. The head mounted electronic device 1_1 according to an embodiment may include a display device 10, a left eye lens 311, a right eye lens 312, a support frame 350, glasses frame legs 341 and 342, an optical member 320, an optical path conversion member 330, and a display device housing portion 120_1.

The third display device 10 illustrated in FIG. 3 may include a third display device 10_3. The third display device 10_3 may be substantially the same as the first display device 10_1 and the second display device 10_2 illustrated in FIG. 2. The display device 10 will be described later with reference to FIGS. 4 and 5.

The display device housing portion 120_1 may include the display device 10, the optical member 320, and the optical path conversion member 330. An image displayed on the display device 10 may be magnified by the optical member 320, converted in an optical path by the optical path conversion member 330, and provided to a user's right eye through the right eye lens 312. For this reason, a user may view an augmented reality image in which a virtual image displayed on the display device 10 through his/her right eye and a real image seen through the right eye lens 312 may be combined with each other.

It has been illustrated in FIG. 3 that the display device housing portion 120_1 may be disposed at a right end of the support frame 350, but an embodiment of the disclosure is not limited thereto. For example, the display device housing portion 120_1 may be disposed at a left end of the support frame 350, and an image of the display device 10 may be provided to a user's left eye. As another example, the display device housing portions 120_1 may be disposed at both the left and right ends of the support frame 350, and the user may view an image displayed on the display device 10 through both his/her left and right eyes.

FIG. 4 is an exploded perspective view illustrating a display device 10 according to an embodiment.

Referring to FIG. 4, the display device 10 according to an embodiment may be a device that displays a moving image or a still image. The display device 10 according to an embodiment may be applied to portable electronic devices such as mobile phones, smartphones, tablet personal computers (PCs), mobile communication terminals, electronic notebooks, electronic books, portable multimedia players (PMPs), navigation devices, and ultra mobile PCs (UMPCs). For example, the display device 10 may be applied as a display portion of televisions, laptop computers, monitors, billboards, or the Internet of Things (IOTs). As another example, the display device 10 may be applied to smart watches, watch phones, or head mounted displays (HMDs) for realizing virtual reality and augmented reality.

The display device 10 according to an embodiment may include a display panel 410, a heat dissipation layer 420, a circuit board 430, a driving circuit 440, and a power supply circuit 450.

The display panel 410 may have a shape similar to a rectangular shape in plan view. For example, the display panel 410 may have a shape similar to a rectangular shape, in plan view, having short sides in a first direction X and long sides in a second direction Y intersecting the first direction X. In the display panel 410, a corner where the short side in the first direction X and the long side in the second direction Y meet may be rounded with a curvature (e.g., predetermined or selectable curvature) or right-angled. The shape of the display panel 410 in plan view is not limited to the rectangular shape, and may be a shape similar to other polygonal shapes, a circular shape, or an elliptical shape. A shape of the display device 10 in plan view may follow the shape of the display panel 410 in plan view, but an embodiment of the disclosure is not limited thereto.

The display panel 410 may include a display area DA and a non-display area NDA. A display area DA may be positioned at the center of the display panel 410, and may occupy most of an area of the display panel 410. A non-display area NDA may surround an edge of the display area DA.

The heat dissipation layer 420 may overlap the display panel 410 in a third direction Z, which is a thickness direction of the display panel 410. The heat dissipation layer 420 may be disposed on a surface, for example a rear surface of the display panel 410. The heat dissipation layer 420 may serve to dissipate heat generated from the display panel 410. The heat dissipation layer 420 may include a layer made of graphite or metal such as silver (Ag), copper (Cu), aluminum (Al), or a combination thereof having high thermal conductivity.

The circuit board 430 may be positioned in the non-display area NDA of the display panel 410 using a conductive adhesive member such as an anisotropic conductive film. The circuit board 430 may be a flexible printed circuit board or a flexible film having a flexible material. It has been illustrated in FIG. 4 that the circuit board 430 may be unbent, but the circuit board 430 may be bent. An end of the circuit board 430 may be disposed on the rear surface of the display panel 410. An end of the circuit board 430 may be an end opposite to another end of the circuit board 430 electrically connected to multiple pads of a pad area of the display panel 410 using the conductive adhesive member.

The driving circuit 440 may receive digital video data and timing signals from the outside. The driving circuit 440 may generate a scan timing control signal, an emission timing control signal, and a data timing control signal for controlling the display panel 410 according to the timing signals.

The power supply circuit 450 may generate multiple panel driving voltages according to an external source voltage. For example, the power supply circuit 450 may generate a first driving voltage (e.g., VSS), a second driving voltage (e.g., VDD), and a third driving voltage (e.g., VINT) and supply the first driving voltage, the second driving voltage, and the third driving voltage to the display panel 410.

Each of the driving circuit 440 and the power supply circuit 450 may be an integrated circuit (IC) and attached to a surface of the circuit board 430.

FIG. 5 is an enlarged plan view of a display area DA of a display panel 410 of FIG. 4.

Referring to FIG. 5, the display area DA according to an embodiment may include an emission area EA and a non-emission area NLA.

The emission area EA may include a first emission area EA1, a second emission area EA2, and a third emission area EA3 that emit light of different colors. The first to third emission areas EA1, EA2, and EA3 may emit red, green, or blue light, respectively, and colors of the light emitted from the first to third emission areas EA1, EA2, and EA3 may be different from each other depending on types of light emitting elements ED to be described later. For example, the first emission area EA1 may emit red light of a first color, the second emission area EA2 may emit green light of a second color and the third emission area EA3 may emit blue light of a third color, but the disclosure is not limited thereto. Although the first to third emission areas EA1, EA2, and EA3 may be shown as having the same size and shape, the disclosure is not limited thereto. The size and shape of each of the first to third emission areas EA1, EA2, and EA3 may be freely adjusted depending on required characteristics.

The first to third emission areas EA1, EA2, and EA3 may be defined by a first opening OP1 and a second opening OP2. The second opening OP2 may completely surround the first opening OP1 in plan view, and the second opening OP2 may be completely surrounded by the non-emission area NLA in plan view.

In some embodiments, at least one first emission area EA1, at least one second emission area EA2 and at least one third emission area EA3, which may be disposed to be adjacent to one another, may constitute one pixel group PXG. The pixel group PXG may be a minimum unit for emitting white light. However, various modifications may be made in the type and/or number of the first to third emission areas EA1, EA2, and EA3 constituting the pixel group PXG depending on the embodiments.

The non-emission area NLA may be positioned to surround the emission area EA.

The non-emission area NLA may shield light emitted from each of the first to third emission areas EA1, EA2, and EA3. For this reason, the non-emission area NLA may assist so that light emitted from the first to third emission areas EA1, EA2, and EA3 may not be mixed.

Each of the first to third emission areas EA1, EA2, and EA3 may include a ninth via VA9 inside. For convenience of explanation, the ninth via VA9 may be positioned inside the first opening OP1 in the drawing, but the disclosure is not limited thereto. According to the embodiment, in plan view, the ninth via VA9 may be positioned between the first opening OP1 and the second opening OP2, or in a portion overlapping the non-emission area NLA. The ninth via VA9 will be described later.

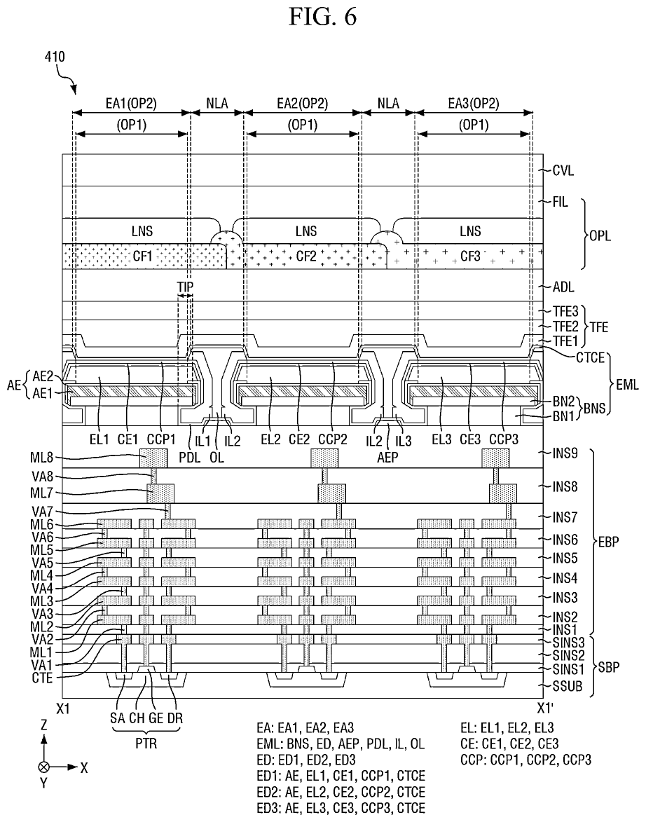

FIG. 6 is a schematic cross-sectional view of a display panel according to an embodiment taken along line X1-X1′ in FIG. 5.

Referring to FIG. 6, the display panel 410 may include a semiconductor backplane SBP, a light emitting element backplane EBP, a light emitting element layer EML, an encapsulation layer TFE, an optical layer OPL, and a cover layer CVL.

The semiconductor backplane SBP may include a semiconductor substrate SSUB including multiple transistors PTR, multiple semiconductor insulating films covering the transistors PTR, and multiple contact terminals CTE electrically connected to the transistors PTR, respectively.

The semiconductor substrate SSUB may be a silicon substrate, a germanium substrate, or a silicon-germanium substrate. The semiconductor substrate SSUB may be a substrate doped with first-type impurities. Multiple well regions may be disposed in an upper surface of the semiconductor substrate SSUB. The well regions may be regions doped with second-type impurities. The second-type impurities may be different from the first-type impurities described above. For example, in case that the first-type impurities are p-type impurities, the second-type impurities may be n-type impurities. As another example, in case that the first-type impurities are n-type impurities, the second-type impurities may be p-type impurities.

Each of the well regions may include a source region SA corresponding to a source electrode of the transistor PTR, a drain region DR corresponding to a drain electrode of the transistor PTR, and a channel region CH disposed between the source region SA and the drain region DR.

Each of the source region SA and the drain region DR may be a region doped with the first-type impurities. A gate electrode GE of the transistor PTR may overlap the well region in the third direction Z. The channel region CH may overlap the gate electrode GE in the third direction Z. The source region SA may be disposed on a side of the gate electrode GE, and the drain region DR may be disposed on another side of the gate electrode GE.

A first insulating layer SINS1 may be disposed on the semiconductor substrate SSUB. The first insulating layer SINS1 may be a silicon carbonitride (SiCN) or silicon oxide (SiOx)-based inorganic film, but an embodiment of the disclosure is not limited thereto.

A second insulating layer SINS2 may be disposed on the first insulating layer SINS1. The second insulating layer SINS2 may be a silicon oxide (SiOx)-based inorganic film, but an embodiment of the disclosure is not limited thereto.

The contact terminals CTE may be disposed on the second insulating layer SINS2. Each of the contact terminals CTE may be electrically connected to any one of the gate electrode GE, the source region SA, and the drain region DR of each of the transistors PTR through a hole penetrating through the first insulating layer SINS1 and the second insulating layer SINS2.

Each of the contact terminals CTE may be made of any one of copper (Cu), aluminum (Al), tungsten (W), molybdenum (Mo), chromium (Cr), gold (Au), titanium (Ti), nickel (Ni), and neodymium (Nd), alloys thereof, or a combination thereof.

A third insulating layer SINS3 may be disposed on side surfaces of the contact terminals CTE. An upper surface of each of the contact terminals CTE may be exposed without being covered by the third insulating layer SINS3. The third insulating layer SINS3 may be a silicon oxide (SiOx)-based inorganic film, but an embodiment of the disclosure is not limited thereto.

The semiconductor substrate SSUB may be replaced with a glass substrate or a polymer resin substrate such as a polyimide substrate. Thin film transistors may be disposed on the glass substrate or the polymer resin substrate. The glass substrate may be a rigid substrate that may not be bent, and the polymer resin substrate may be a flexible substrate that may be bent or curved.

The light emitting element backplane EBP may include first to eighth metal layers ML1 to ML8, multiple first to eighth vias VA1 to VA8, and first to ninth interlayer insulating layers INS1 to INS9.

The first to eighth metal layers ML1 to ML8 serve to implement circuits of the light emitting elements ED1 to ED3 by connecting the contact terminals CTE exposed from the semiconductor backplane SBP to each other.

A first interlayer insulating layer INS1 may be disposed on the semiconductor backplane SBP. Each of first vias VA1 may penetrate through the first interlayer insulating layer INS1 to extend to the contact terminal CTE exposed from the semiconductor backplane SBP. Each of the first metal layers ML1 may be disposed on the first interlayer insulating layer INS1 and may extend to the first via VA1.

A second interlayer insulating layer INS2 may be disposed on the first interlayer insulating layer INS1 and the first metal layers ML1. Each of second vias VA2 may penetrate through the second interlayer insulating layer INS2 to extend to the exposed first metal layer ML1. Each of the second metal layers ML2 may be disposed on the second interlayer insulating layer INS2 and may extend to the second via VA2.

A third interlayer insulating layer INS3 may be disposed on the second interlayer insulating layer INS2 and the second metal layers ML2. Each of third vias VA3 may penetrate through the third interlayer insulating layer INS3 to extend to the exposed second metal layer ML2. Each of the third metal layers ML3 may be disposed on the third interlayer insulating layer INS3 and may extend to the third via VA3.

A fourth interlayer insulating layer INS4 may be disposed on the third interlayer insulating layer INS3 and the third metal layers ML3. Each of fourth vias VA4 may penetrate through the fourth interlayer insulating layer INS4 to extend to the exposed third metal layer ML3. Each of the fourth metal layers ML4 may be disposed on the fourth interlayer insulating layer INS4 and may extend to the fourth via VA4.

A fifth interlayer insulating layer INS5 may be disposed on the fourth interlayer insulating layer INS4 and the fourth metal layers ML4. Each of fifth vias VA5 may penetrate through the fifth interlayer insulating layer INS5 to extend to the exposed fourth metal layer ML4. Each of the fifth metal layers ML5 may be disposed on the fifth interlayer insulating layer INS5 and may extend to the fifth via VA5.

A sixth interlayer insulating layer INS6 may be disposed on the fifth interlayer insulating layer INS5 and the fifth metal layers ML5. Each of sixth vias VA6 may penetrate through the sixth interlayer insulating layer INS6 to extend to the exposed fifth metal layer ML5. Each of the sixth metal layers ML6 may be disposed on the sixth interlayer insulating layer INS6 and may extend to the sixth via VA6.

A seventh interlayer insulating layer INS7 may be disposed on the sixth interlayer insulating layer INS6 and the sixth metal layers ML6. Each of seventh vias VA7 may penetrate through the seventh interlayer insulating layer INS7 to extend to the exposed sixth metal layer ML6. Each of the seventh metal layers ML7 may be disposed on the seventh interlayer insulating layer INS7 and may extend to the seventh via VA7.

An eighth interlayer insulating layer INS8 may be disposed on the seventh interlayer insulating layer INS7 and the seventh metal layers ML7. Each of eighth vias VA8 may penetrate through the eighth interlayer insulating layer INS8 to extend to the exposed seventh metal layer ML7. Each of the eighth metal layers ML8 may be disposed on the eighth interlayer insulating layer INS8 and may extend to the eighth via VA8.

The contact terminals CTE of the semiconductor backplane SBP and the first to sixth metal layers ML1 to ML6 of the light emitting element backplane EBP may be electrically connected to the drain region DR, the source region SA, and the gate electrode GE of the transistor PTR. The seventh and eighth metal layers ML7 and ML8 may not be electrically connected to the source region SA and the gate electrode GE, but may be electrically connected to the drain region DR.

The first to eighth metal layers ML1 to ML8 and the first to eighth vias VA1 to VA8 may be made of substantially a same material. Each of the first to eighth metal layers ML1 to ML8 and the first to eighth vias VA1 to VA8 may be made of any one of copper (Cu), aluminum (Al), tungsten (W), molybdenum (Mo), chromium (Cr), gold (Au), titanium (Ti), nickel (Ni), and neodymium (Nd), alloys thereof, or a combination thereof. The first to eighth vias VA1 to VA8 may be made of substantially a same material. The first to eighth interlayer insulating layers INS1 to INS8 may be silicon oxide (SiOx)-based inorganic films, but an embodiment of the disclosure is not limited thereto.

A ninth interlayer insulating layer INS9 may be disposed on the eighth interlayer insulating layer INS8 and the eighth metal layers ML8. The ninth interlayer insulating layer INS9 may be a silicon oxide (SiOx)-based inorganic film, but an embodiment of the disclosure is not limited thereto.

The light emitting element layer EML may be disposed on the light emitting element backplane EBP. The light emitting element layer EML may include a bank structure BNS, a light emitting element ED, a residual pattern AEP, a pixel defining layer PDL, and an inorganic layer IL and an organic layer OL.

The bank structure BNS according to an embodiment may be positioned in a portion overlapping the emission area EA. The bank structure BNS may be positioned on the ninth interlayer insulating layer INS9. The bank structure BNS may include a first bank layer BN1 and a second bank layer BN2 which may be sequentially stacked on each other.

The first bank layer BN1 according to an embodiment may include multiple patterns, and the respective patterns may be separated or spaced apart from each other in the first direction X in portions overlapping the first to third emission areas EA1, EA2, and EA3. For example, the first bank layer BN1 may have island patterns. Each island of the first bank layer BN1 may have a circular shape or a polygonal shape such as a triangular shape or a rectangular shape in plan view.

The second bank layer BN2 according to an embodiment may be disposed on the first bank layer BN1. The second bank layer BN2 may include multiple patterns, and the respective patterns may be separated or spaced apart from each other in the first direction X in the portions overlapping the first to third emission areas EA1, EA2, and EA3. In an embodiment, the second bank layer BN2 may have island patterns. Each island of the second bank layer BN2 may have a circular shape or a polygonal shape such as a triangular shape or a rectangular shape in plan view.

The second bank layer BN2 according to an embodiment may have a tip TIP protruding toward the non-emission area NLA more than the first bank layer BN1. An undercut may be formed between the first bank layer BN1 and the tip TIP of the second bank layer BN2. Details will be described later.

The light emitting element ED according to an embodiment may be disposed on the second bank layer BN2 and the pixel defining layer PDL. The light emitting element ED may include a first light emitting element ED1 disposed in the first emission area EA1, a second light emitting element ED2 disposed in the second emission area EA2, and a third light emitting element ED3 disposed in the third emission area EA3. The first light emitting element ED1 may include a pixel electrode AE, a first light emitting layer EL1, a first cathode electrode CE1, a first capping layer CCP1, and a connection electrode CTCE, the second light emitting element ED2 may include a pixel electrode AE, a second light emitting layer EL2, a second cathode electrode CE2, a second capping layer CCP2, and the connection electrode CTCE, and the third light emitting element ED3 may include a pixel electrode AE, a third light emitting layer EL3, a third cathode electrode CE3, a third capping layer CCP3, and the connection electrode CTCE.

The first to third light emitting elements ED1, ED2, and ED3 overlapping the first to third emission areas EA1, EA2, and EA3, respectively may emit light of different colors depending on materials of a light emitting layer EL. For example, the first light emitting element ED1 may emit red light, which may be light of a first light, the second light emitting element ED2 may emit green light, which may be light of a second color, and the third light emitting element ED3 may emit blue light, which may be light of a third color. However, the disclosure is not limited thereto, and the first to third light emitting elements ED1, ED2, and ED3 overlapping the first to third emission areas EA1, EA2, and EA3, respectively, may also emit light of the same color.

The pixel electrode AE according to an embodiment may be disposed on the second bank layer BN2. The display panel 410 according to an embodiment may include the bank structure BNS forming the undercuts under the pixel electrodes AE, and thus, the pixel electrodes AE positioned to overlap the first to third emission areas EA1, EA2, and EA3 may be formed without a separate etching process. In other words, in the display panel 410 according to an embodiment, the second bank layer BN2 may include the tips TIP protruding more than the first bank layer BN1, and thus, multiple pixel electrodes AE positioned to be spaced apart from each other may be formed without a separate etching process. For this reason, in the display panel 410 according to an embodiment, the pixel electrodes AE neighboring to each other may be formed to have a very small gap therebetween, and for this reason, the display panel 410 may be applied to an electronic device requiring high resolution. The manufacturing method will be described later.

The pixel electrode AE according to an embodiment may include a first layer AE1 and a second layer AE2 which may be sequentially stacked on each other.

The first layer AE1 may include metal, and for example, the first layer AE1 may include any one of copper (Cu), aluminum (Al), tungsten (W), molybdenum (Mo), chromium (Cr), gold (Au), titanium (Ti), nickel (Ni), neodymium (Nd), or a combination thereof. According to an embodiment, the first layer AE1 may be formed of a single layer, and may have a double layer structure in which a metal material may be stacked on each other on a transparent conductive oxide (TCO).

The second layer AE2 may include a transparent conductive oxide (TCO), and for example, may include one or more of indium tin oxide (ITO), indium zinc oxide (IZO), indium tin zinc oxide (ITZO), zinc indium tin oxide (ZITO), indium gallium zinc oxide (IGZO) and zinc tin oxide (ZTO).

A residual pattern AEP according to an embodiment may be disposed on the ninth interlayer insulating layer INS9 in a portion overlapping the non-emission area NLA. The residual pattern AEP will be described later.

The pixel defining layer PDL according to an embodiment may be positioned on the pixel electrode AE and the ninth interlayer insulating layer INS9. The pixel defining layer PDL may define the first opening OP1 and expose the pixel electrode AE in a portion overlapping the first opening OP1.

The light emitting layer EL according to an embodiment may be positioned on the pixel electrode AE and the pixel defining layer PDL. The light emitting layer EL according to an embodiment may include a first light emitting layer EL1, a second light emitting layer EL2, and a third light emitting layer EL3 positioned to respectively overlap the first to third emission areas EA1, EA2, and EA3. The first to third light emitting layers EL1, EL2, and EL3 may emit different light. For example, the first light emitting layer EL1 disposed in the first emission area EA1 may emit red light having a peak wavelength in a range of about 610 nm to about 650 nm, the second light emitting layer EL2 disposed in the second emission area EA2 may emit green light having a peak wavelength in a range of about 510 nm to about 550 nm, and the third light emitting layer EL3 disposed in the third emission area EA3 may emit blue light having a peak wavelength in a range of about 440 nm to about 480 nm. The first to third emission areas EA constituting one pixel may include the light emitting elements emitting light of different colors to express a white gradation. As another example, the light emitting layer EL may include multiple materials emitting light of different colors, such that a single light emitting layer may emit mixed light.

The light emitting layer EL according to an embodiment may include the bank structure BNS forming the undercuts thereunder, and thus the first to third light emitting layers EL1, EL2, and EL3 positioned to overlap the first to third emission areas EA1, EA2, and EA3 may be formed without a separate fine metal mask. In other words, in the display panel 410 according to an embodiment, the second bank layer BN2 may include the tips TIP protruding more than the first bank layer BN1, and thus multiple light emitting layers EL positioned to be spaced apart from each other may be formed without a separate fine metal mask. For this reason, in the display panel 410 according to an embodiment, the light emitting layers EL neighboring to each other may be formed to have a very small gap therebetween, and for this reason the display panel 410 may be applied to an electronic device requiring high resolution. The manufacturing method will be described later.

A cathode electrode CE according to an embodiment may be disposed on the light emitting layer EL and the pixel defining layer PDL.

The cathode electrode CE according to an embodiment may include a first cathode electrode CE1, a second cathode electrode CE2, and a third cathode electrode CE3 positioned to overlap the first to third emission areas EA1, EA2, and EA3, respectively. The first to third cathode electrodes CE1, CE2, and CE3 according to an embodiment may be spaced apart from each other in the first direction X. The first cathode electrode CE1 may be disposed on the first light emitting layer EL1, the second cathode electrode CE2 may be disposed on the second light emitting layer EL2, and the third cathode electrode CE3 may be disposed on the third light emitting layer EL3.

The cathode electrode CE according to an embodiment may include the bank structure BNS forming the undercuts thereunder, and thus the first to third light emitting layers EL1, EL2, and EL3 positioned to overlap the first to third emission areas EA1, EA2, and EA3 may be formed without a separate fine metal mask. In other words, in the display panel 410 according to an embodiment, the second bank layer BN2 may include the tips TIP protruding more than the first bank layer BN1, and thus multiple cathode electrodes CE positioned to be spaced apart from each other may be formed without a separate fine metal mask. The process of forming the cathode electrode CE according to an embodiment may have a higher step coverage than the process of forming the light emitting layer EL. Accordingly, the cathode electrode CE according to an embodiment may entirely cover the light emitting layer EL. The manufacturing method will be described later.

The cathode electrode CE may include a transparent conductive material. As an example, the cathode electrode CE may be made of a transparent conductive material (TCO) such as ITO or IZO capable of transmitting light therethrough or a semi-transmissive conductive material such as magnesium (Mg), silver (Ag), or an alloy of magnesium (Mg) and silver (Ag). In case that the cathode electrode CE is made of the semi-transmissive conductive material, light emission efficiency may be increased by a micro cavity.

The capping layer CCP according to an embodiment may be disposed on the cathode electrode CE and the pixel defining layer PDL. The capping layer CCP according to an embodiment may function as an etch stopper and protect the cathode electrode CE from moisture infiltration during the manufacturing process of the display panel 410.

The capping layer CCP according to an embodiment may include a first capping layer CCP1, a second capping layer CCP2, and a third capping layer CCP3 positioned to overlap the first to third emission areas EA1, EA2, and EA3, respectively. The first to third capping layers CCP1, CCP2, and CCP3 according to an embodiment may be spaced apart from each other in the first direction X. The first capping layer CCP1 may be positioned on the first cathode electrode CE1, the second capping layer CCP2 may be positioned on the second cathode electrode CE2, and the third capping layer CCP3 may be positioned on the third cathode electrode CE3.

The capping layer CCP may include a transparent conductive oxide (TCO), and for example, may include one or more of indium tin oxide (ITO), indium zinc oxide (IZO), indium tin zinc oxide (ITZO), zinc indium tin oxide (ZITO), indium gallium zinc oxide (IGZO), and zinc tin oxide (ZTO).

The inorganic layer IL according to an embodiment may be positioned on the pixel defining layer PDL and the capping layer CCP in a portion overlapping the non-emission area NLA. The inorganic layer IL according to an embodiment may define a second opening OP2 and expose a capping layer CCP in a portion overlapping the second opening OP2.

The inorganic layer IL according to an embodiment may protect the light emitting element ED from the etching process included in the manufacturing process of the display panel 410.

The inorganic layer IL may include a first inorganic layer IL1 surrounding the first emission area EA1, a second inorganic layer IL2 surrounding the second emission area EA2, and a third inorganic layer IL3 surrounding the third emission area EA3. The first to third inorganic layers IL1, IL2, and IL3 may be spaced apart from each other in a portion overlapping the non-emission area NLA. The first inorganic layer IL1 may cover a portion of the first light emitting element ED1, the second inorganic layer IL2 may cover a portion of the second light emitting element ED2, and the third inorganic layer IL3 may cover a portion of the third light emitting element ED3.

The inorganic layer IL may include an inorganic insulating material, and for example may include at least one of a silicon nitride, a silicon oxynitride, or a silicon oxide.

The organic layer OL according to an embodiment may be positioned on the pixel defining layer PDL in a portion overlapping the non-emission area NLA. The organic layer OL according to an embodiment may planarize a step formed by the first to third inorganic layers IL1, IL2, and IL3 in a portion overlapping the non-emission area NLA.

The organic layer OL may include an organic insulating material with fluidity such as hexamethyl disiloxane (HMDSO).

The connection electrode CTCE according to an embodiment may be positioned on the capping layer CCP and the organic layer OL. The connection electrode CTCE may be a common layer positioned entirely in a portion overlapping the emission area EA and the non-emission area NLA.

The connection electrode CTCE may be electrically connected to the first to third cathode electrodes CE1, CE2, and CE3. Specifically, the connection electrode CTCE may be in contact with the first to third capping layers CCP1, CCP2, and CCP3, and electrically connected to the first to third cathode electrodes CE1, CE2, and CE3 through the first to third capping layers CCP1, CCP2, and CCP3.

The connection electrode CTCE according to an embodiment may include a transparent conductive oxide (TCO), and for example, may include one or more of indium tin oxide (ITO), indium zinc oxide (IZO), indium tin zinc oxide (ITZO), zinc indium tin oxide (ZITO), indium gallium zinc oxide (IGZO), and zinc tin oxide (ZTO).

The encapsulation layer TFE may be disposed on the light emitting element layer EML. The encapsulation layer TFE may prevent oxygen or moisture from penetrating into the light emitting element layer EML. The encapsulation layer TFE may include a first encapsulation layer TFE1, a second encapsulation layer TFE2, and a third encapsulation layer TFE3 which may be sequentially stacked on each other. The first encapsulation layer TFE1 may be disposed on the connection electrode CTCE, the second encapsulation layer TFE2 may be disposed on the first encapsulation layer TFE1, and the third encapsulation layer TFE3 may be disposed on the second encapsulation layer TFE2.

The first encapsulation layer TFEL and the third encapsulation layer TFE3 may be made of an inorganic insulating material. As an example, the first encapsulation layer TFE1 and the third encapsulation layer TFE3 may include silicon nitride (SiNₓ), silicon oxynitride (SiON), silicon oxide (SiOₓ), titanium oxide (TiOₓ), aluminum oxide (AlOₓ), or a combination thereof.

The second encapsulation layer TFE2 may be made of an organic material. As an example, the second encapsulation layer TFE2 may include an acrylic resin, an epoxy resin, a silicone resin, a silicone acrylic resin, a phenolic resin, a polyamide resin, a polyimide resin, the like, or a combination thereof.

An adhesive layer ADL may be a layer for adhering the encapsulation layer TFE and the optical layer OPL to each other. The adhesive layer ADL may be a double-sided adhesive member. The adhesive layer ADL may be a transparent adhesive member such as a transparent adhesive or a transparent adhesive resin.

The optical layer OPL may include multiple first to third color filters CF1, CF2, and CF3, multiple lenses LNS, and a filling layer FIL.

The first to third color filters CF1, CF2, and CF3 may be disposed on the adhesive layer ADL. The first to third color filters CF1, CF2, and CF3 may include colorants such as dyes or pigments absorbing light of wavelength bands other than light of a specific wavelength band, and may be disposed to correspond to the colors of light emitted from the emission areas EA.

The first color filter CF1 may be a red color filter disposed to overlap the first emission area EA1 and may transmit only the red light through the first color filter CF1. The second color filter CF2 may be a green color filter disposed to overlap the second emission area EA2 and may transmit only the green light through the second color filter, and the third color filter CF3 may be a blue color filter disposed to overlap the third emission area EA3 and may transmit only the blue light through the third color filter CF3.

The lenses LNS may be disposed on the first color filter CF1, the second color filter CF2, and the third color filter CF3, respectively. The lenses LNS may be structures for increasing a ratio of light directed to a front surface of the display panel 410. The lenses LNS may have a convex cross-sectional shape bulging in an upward direction.

The filling layer FIL may be disposed on the lenses LNS. The filling layer FIL may have a refractive index (e.g., predetermined or selectable refractive index) so that light travels in the third direction Z at an interface between the lenses LNS and the filling layer FIL. The filling layer FIL may be a planarizing layer. The filling layer FIL may be an organic film made of an acrylic resin, an epoxy resin, a phenolic resin, a polyamide resin, a polyimide resin, the like, or a combination thereof.

The cover layer CVL may be disposed on the optical layer OPL. The cover layer CVL may be a glass substrate or a resin substrate that may include a polymer resin. In case that the cover layer CVL is the glass substrate, the cover layer CVL may be attached onto the filling layer FIL. The filling layer FIL may serve to adhere the cover layer CVL. In case that the cover layer CVL is the glass substrate, the cover layer CVL may serve as an encapsulation substrate. In case that the cover layer CVL is the polymer resin such as the resin, the cover layer CVL may be applied (e.g., directly applied) onto the filling layer FIL.

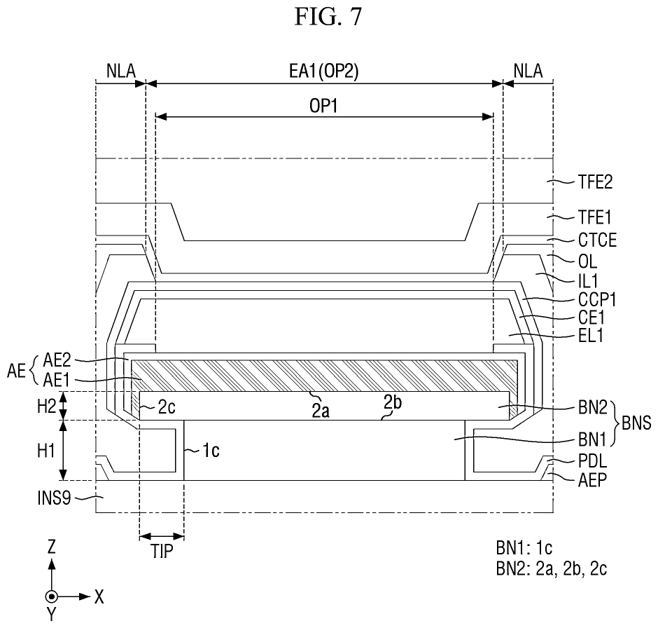

FIG. 7 is an enlarged schematic cross-sectional view of a light emitting element layer EML and an encapsulation layer TFE positioned to overlap a first emission area EA1 in FIG. 6.

Referring to FIG. 7, the bank structure BNS according to an embodiment may include a first bank layer BN1 and a second bank layer BN2 having different materials.

The first bank layer BN1 according to an embodiment may be positioned in a portion overlapping the first emission area EA1 and may not overlap the non-emission area NLA. The first bank layer BN1 may be positioned on the ninth interlayer insulating layer INS9.

In some embodiments, the first bank layer BN1 may include a side surface 1c. The side surface 1c of the first bank layer BN1 may be a surface facing the non-emission area NLA. The side surface 1c of the first bank layer BN1 may be entirely covered by the pixel defining layer PDL, and an entirety of the side surface 1c of the first bank layer BN1 may be in contact with the pixel defining layer PDL.

The first bank layer BN1 may include an inorganic insulating material, and for example may include any one of silicon nitride, silicon oxynitride, silicon oxide, and a combination thereof.

The second bank layer BN2 according to an embodiment may be positioned on the first bank layer BN1.

In some embodiments, the second bank layer BN2 may include an upper surface 2a, a lower surface 2b, and a side surface 2c. The upper surface 2a of the second bank layer BN2 may be a surface facing the pixel electrode AE, the lower surface 2b of the second bank layer BN2 may be a surface facing the first bank layer BN1, and the side surface 2c of the second bank layer BN2 may be a surface connecting the upper surface 2a and the lower surface 2b. The side surface 2c of the second bank layer BN2 may be a surface facing the non-emission area NLA.

The upper surface 2a and the side surface 2c of the second bank layer BN2 may be covered by the pixel electrode AE and may be in contact with the pixel electrode AE. The lower surface 2b of the second bank layer BN2 may be covered by the pixel defining layer PDL and may be in contact with the pixel defining layer PDL.

In the manufacturing process of the bank structure BNS, the first bank layer BN1 and the second bank layer BN2 may be formed by performing the same etching process. At this time, the second bank layer BN2 may have higher etch resistance than the first bank layer BN1. In other words, the etch rate of the second bank layer BN2 may be lower than the etch rate of the first bank layer BN1 in respect to the same etchant. Accordingly, the second bank layer BN2 may have a tip TIP protruding more than the first bank layer BN1, and for this reason, the side surface 2c of the second bank layer BN2 may protrude toward the non-emission area NLA more than the side surface Ic of the first bank layer BN1. For example, an undercut may be formed between the side surface Ic of the first bank layer BN1 and the tip TIP of the second bank layer BN2. The manufacturing method will be described later.

The second bank layer BN2 may include an inorganic insulating material, for example, any one of silicon nitride, silicon oxynitride, silicon oxide, and a combination thereof. As described above, the first bank layer BN1 and the second bank layer BN2 may include different materials. Accordingly, in case that the first bank layer BN1 is one of silicon nitride, silicon oxy nitride, silicon oxide, and a combination thereof, the second bank layer BN2 may include a material different from that of the first bank layer BN1. For example, in case that the first bank layer BN1 is silicon nitride, the second bank layer BN2 may be any one of silicon oxynitride or silicon oxide, excluding silicon nitride.

In some embodiments, a height H1 of the first bank layer BN1 may be greater than a height H2 of the second bank layer BN2.

The pixel electrode AE may be disposed on and cover an upper surface 2a and a side surface 2c of the second bank layer BN2. Specifically, the first layer AE1 of the pixel electrode AE may cover the upper surface 2a and the side surface 2c of the second bank layer BN2 and be in contact with the upper surface 2a and the side surface 2c of the second bank layer BN2. The second layer AE2 of the pixel electrode AE may cover the upper surface 2a and the side surface 2c of the second bank layer BN2. According to an embodiment, the second layer AE2 may not cover the side surface 2c of the second bank layer BN2. The residual pattern AEP will be described later.

The pixel defining layer PDL may be positioned on the pixel electrode AE and the residual pattern AEP. The pixel defining layer PDL may be positioned to surround the edge of the pixel electrode AE. In other words, the pixel defining layer PDL may expose the pixel electrode AE at a portion overlapping the first opening OP1 and may surround the first opening OP1.

The pixel defining layer PDL may be formed in the same thickness according to the profile of the underlying structure. Accordingly, the pixel defining layer PDL may include a step. The pixel defining layer PDL may be in contact with a portion of the pixel electrode AE, a portion of the lower surface 2b of the second bank layer BN2, and a side surface Ic of the first bank layer BN1.

The pixel defining layer PDL may include an inorganic insulating material, for example, at least one of silicon nitride, silicon oxynitride, silicon oxide, titanium oxide, aluminum oxide, tantalum oxide, hafnium oxide, zinc oxide, and amorphous silicon, but is not limited thereto.

The first light emitting layer EL1 according to an embodiment may be positioned on the pixel electrode AE. The first light emitting layer EL1 may be positioned in a portion overlapping the first emission area EA1 and the non-emission area NLA. Specifically, the first light emitting layer EL1 may be in contact with the pixel electrode AE in a portion overlapping the first opening OP1 and be in contact with the pixel defining layer PDL in a portion overlapping the second opening OP2. The first light emitting layer EL1 according to an embodiment may be formed on the pixel electrode AE without a separate fine metal mask in the manufacturing process. The manufacturing method will be described later.

The first cathode electrode CE1 according to an embodiment may be positioned on the first light emitting layer EL1. The first cathode electrode CE1 may be positioned in a portion overlapping the first emission area EA1 and the non-emission area NLA. Specifically, the first cathode electrode CE1 may be in contact with the first light emitting layer EL1 in a portion overlapping the first emission area EA1 and may be in contact with the pixel defining layer PDL in a portion overlapping the non-emission area NLA. As described above, since the first cathode electrode CE1 may be formed by a process having a higher step coverage than the first light emitting layer EL1, the first cathode electrode CE1 may entirely cover the first light emitting layer EL1. The manufacturing method will be described later.

The first capping layer CCP1 according to an embodiment may be positioned on the first cathode electrode CE1. The first capping layer CCP1 may be positioned in a portion overlapping the first emission area EA1 and the non-emission area NLA. Specifically, the first capping layer CCP1 may be in contact with the first cathode electrode CE1 in a portion overlapping the first emission area EA1, and may be in contact with the pixel defining layer PDL in a portion overlapping the non-emission area NLA. As described above, the first capping layer CCP1 may be formed by a process having a higher step coverage than the first cathode electrode CE1. Accordingly, the first capping layer CCP1 may entirely cover the first cathode electrode CE1, and may cover the portion of the pixel defining layer PDL which the first cathode electrode CE1 does not cover. The manufacturing method will be described later.

The connection electrode CTCE may be positioned on the first capping layer CCP1 in a portion overlapping the first opening OP1. The connection electrode CTCE may contact the first capping layer CCP1 at a portion overlapping the first opening OP1. The connection electrode CTCE may be electrically connected to the first cathode electrode CE1 through the first capping layer CCP1.

The correlation structure of the connection electrode CTCE, the first inorganic layer IL1, and the organic layer OL in the portion overlapping the non-emission area NLA will be described later.

The first encapsulation layer TFE1 and the second encapsulation layer TFE2 may be formed entirely on the connection electrode CTCE. The first encapsulation layer TFE1 may be in contact with the connection electrode CTCE. The first encapsulation layer TFEL and the second encapsulation layer TFE2 may overlap the tip TIP of the second bank layer BN2 in the third direction Z. Other redundant descriptions will be omitted.

For convenience of description, the light emitting element layer EML and the encapsulation layer TFE positioned in the portion overlapping the first emission area EA1 may be shown and described, but the light emitting element layer EML and the encapsulation layer TFE positioned in the portion overlapping the second emission area EA2 and the third emission area EA3 may also have the same structure and characteristics. Redundant descriptions will be omitted.

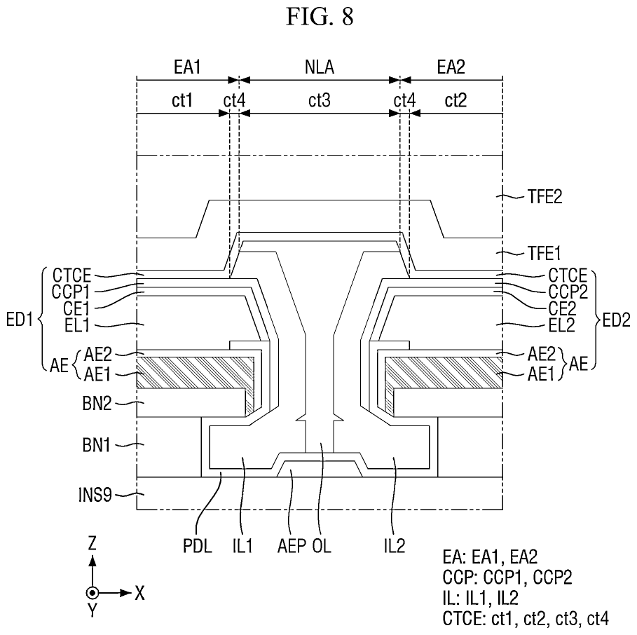

FIG. 8 an enlarged schematic cross-sectional view of a light emitting element layer EML and an encapsulation layer TFE positioned to overlap a non-emission area NLA positioned between the first emission area EA1 and a second emission area EA2.

Referring to FIG. 8, the first emission area EA1 and the second emission area EA2 may be spaced apart with the non-emission area NLA between the first emission area EA1 and the second emission area EA2.

The residual pattern AEP according to an embodiment may be positioned on the ninth interlayer insulating layer INS9 in a portion overlapping the non-emission area NLA. The residual pattern AEP according to an embodiment may be a result of a material forming the pixel electrode AE formed by being disconnected (or spaced apart) and not being electrically connected with the pixel electrode AE due to the tip TIP of the second bank layer BN2 during the manufacturing process of the pixel electrode AE. Accordingly, the residual pattern AEP and the pixel electrode AE may include a same material. In case that the pixel electrode AE is a multilayer structure, the stacked structure of the residual pattern AEP may be the same as the stacked structure of the pixel electrode AE.

The pixel defining layer PDL according to an embodiment may be positioned on the ninth interlayer insulating layer INS9 and the residual pattern AEP in a portion overlapping the non-emission area NLA. The pixel defining layer PDL covering the edge of the first light emitting element ED1 and the pixel defining layer PDL covering the edge of the second light emitting element ED2 may be integral with each other. In other words, the pixel defining layer PDL overlapping the first emission area EA1 and the pixel defining layer PDL overlapping the second emission area EA2 may extend to each other by a portion of pixel defining layer PDL covering the residual pattern AEP.

The inorganic layer IL according to an embodiment may be positioned on the pixel defining layer PDL and the capping layer CCP. The inorganic layer IL may be in contact with the pixel defining layer PDL and the capping layer CCP. The inorganic layer IL may be positioned surrounding the edge of the capping layer CCP.

The inorganic layer IL may include a first inorganic layer IL1 and a second inorganic layer IL2 spaced apart from each other in a portion overlapping the non-emission area NLA. The first inorganic layer IL1 and the second inorganic layer IL2 may be spaced apart in the first direction X with the organic layer OL between the first inorganic layer IL1 and the second inorganic layer IL2. The first inorganic layer IL1 may cover the first light emitting element ED1 and the bank structure BNS positioned below the first light emitting element ED1, and the second inorganic layer IL2 may cover the second light emitting element ED2 and the bank structure BNS positioned below the second light emitting element ED2. In other words, the first inorganic layer IL1 may be positioned to surround the edge of the first light emitting element ED1, and the second inorganic layer IL2 may be positioned to surround the edge of the second light emitting element ED2.

The organic layer OL according to an embodiment may be positioned on the pixel defining layer PDL and the inorganic layer IL in a portion overlapping the non-emission area NLA. The organic layer OL may be positioned between the first inorganic layer IL1 and the second inorganic layer IL2 in a portion overlapping the non-emission area NLA. As described above, the organic layer OL may planarize the step formed between the first inorganic layer IL1 and the second inorganic layer IL2. Accordingly, the connection electrode CTCE positioned to overlap the first emission area EA1 and the connection electrode CTCE positioned to overlap the second emission area EA2 may be electrically connected without disconnection defects by a portion of the connection electrode CTCE positioned to overlap the non-emission area NLA.

In some embodiments, the connection electrode CTCE may include a first portion ct1 in contact with the first capping layer CCP1, a second portion ct2 in contact with the second capping layer CCP2, and a third portion ct3 in contact with the organic layer OL, and a fourth portion ct4 in contact with the inorganic layer IL. The first portion ct1 and the second portion ct2 may be spaced apart with the third portion ct3 and the fourth portion ct4 disposed between the first portion ct1 and the second portion ct2.

The first cathode electrode CE1, which may be electrically connected to the first capping layer CCP1, may be electrically connected to the first portion ct1 of the connection electrode CTCE. The second cathode electrode CE2, which may be electrically connected to the second capping layer CCP2, may be electrically connected to the second portion ct2 of the connection electrode CTCE. The first portion ct1 and the second portion ct2 of the connection electrode CTCE may be electrically connected to each other through the third portion ct3 the fourth portion ct4. For example, the first cathode electrode CE1 and the second cathode electrode CE2 may be electrically connected to each other through the connection electrode CTCE. Redundant description may be omitted.

The first encapsulation layer TFE1 according to an embodiment may be in contact with the connection electrode CTCE at a portion overlapping the non-emission area NLA. The first encapsulation layer TFE1 and the second encapsulation layer TFE2 may overlap the residual pattern AEP, the inorganic layer IL, and the organic layer OL in the third direction Z in the portion overlapping the non-emission area NLA. Other redundant descriptions will be omitted.

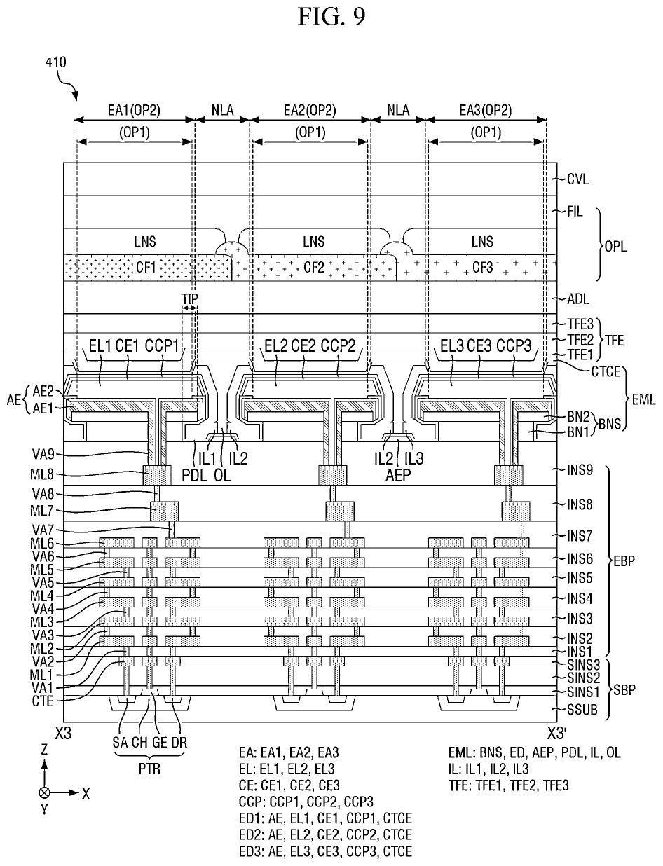

FIG. 9 is a schematic cross-sectional view of a display panel 410 according to an embodiment taken along line X3-X3′ in FIG. 5.

Referring to FIG. 9, the pixel electrode AE included in the display panel 410 according to an embodiment may be electrically connected to the eighth metal layer ML8 through the ninth via VA9. The ninth via VA9 may penetrate the bank structure BNS and the ninth interlayer insulating layer INS9. The pixel electrode AE may be electrically connected to the eighth metal layer ML8 through the ninth via VA9, and then electrically connected to the drain region DR or source region SA of the transistor PTR through the first to eighth vias VA1 to VA8, the first to seventh metal layers ML1 to ML7, and the contact terminal CTE. In other words, in case that the pixel electrode AE according to an embodiment receives a voltage corresponding to the data voltage through the transistor PTR and the cathode electrode CE receives a low potential voltage, the potential difference may be formed between the pixel electrode AE and the cathode electrodes CE, and thus the light emitting layer EL may emit light.

The ninth via VA9 may be made of any one of copper (Cu), aluminum (Al), tungsten (W), molybdenum (Mo), chromium (Cr), gold (Au), titanium (Ti), nickel (Ni), and neodymium (Nd), alloys thereof, or a combination thereof. Other redundant descriptions will be omitted.

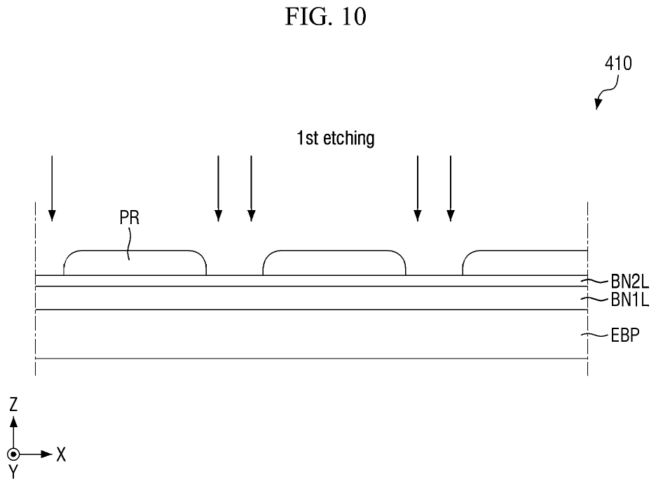

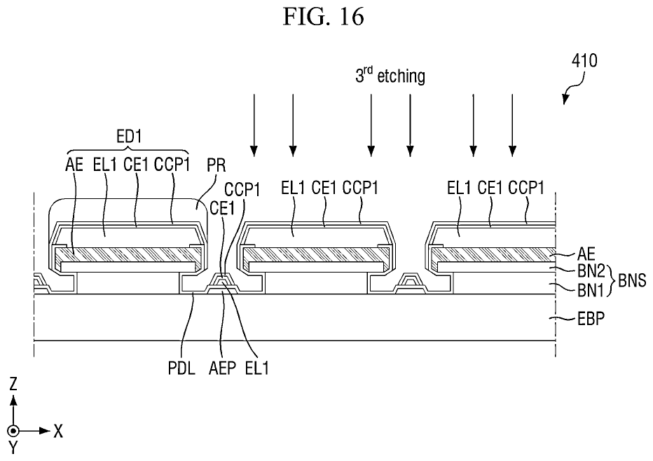

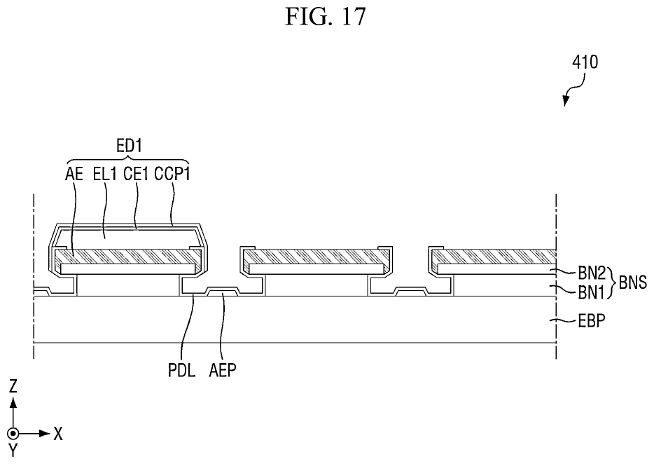

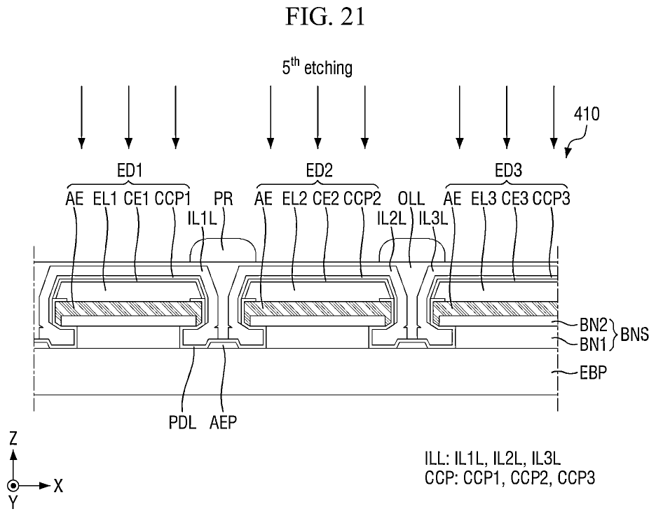

FIGS. 10 to 23 are schematic cross-sectional views sequentially illustrating a manufacturing process of a light emitting element layer EML of a display panel 410 according to an embodiment. Hereinafter, a manufacturing process of the light emitting element layer EML illustrated in FIG. 6 will be described.

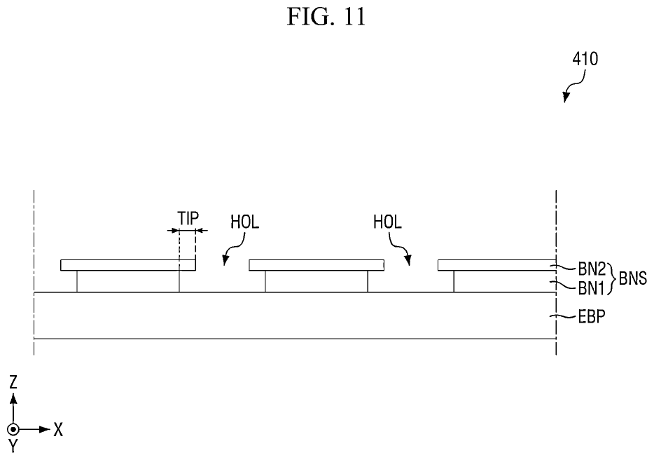

Referring to FIGS. 10 and 11, a first bank material layer BN1L and a second bank material layer BN2L may be formed on the entire surface of the light emitting element backplane EBP. Although not shown in the drawing, the detailed structure of the light emitting element backplane EBP may be the same as described above with reference to FIG. 6.

Subsequently, a photoresist PR may be formed on the second bank material layer BN2L. A photoresist pattern PR may be formed, and ones of the photoresist patterns PR may be spaced apart from each other. Next, a first etching process (1^{st} etching) may be performed using the photoresist patterns PR as a mask.

The first bank material layer BN1L according to an embodiment may have a higher etch rate than the second bank material layer BN2L with respect to the same etchant. Accordingly, in case that performing the same etching process, the second bank layer BN2 may have a tip TIP that protrudes more than the first bank layer BN1, and the bank structure BNS may have an undercut shape. The etchant mentioned above may include all chemical solutions or gases used in the etching process.

In this process, the first bank material layer BN1L and the second bank material layer BN2L in the portion where the photoresist pattern PR may not be formed may be removed, and for this reason, the first bank layer BN1 and the second bank layer BN2 shown in FIG. 6 may result. A hole HOL may be formed in a portion where the first bank material layer BN1L and the second bank material layer BN2L may be removed, and the light emitting element backplane EBP may be exposed in a portion overlapping the hole HOL.

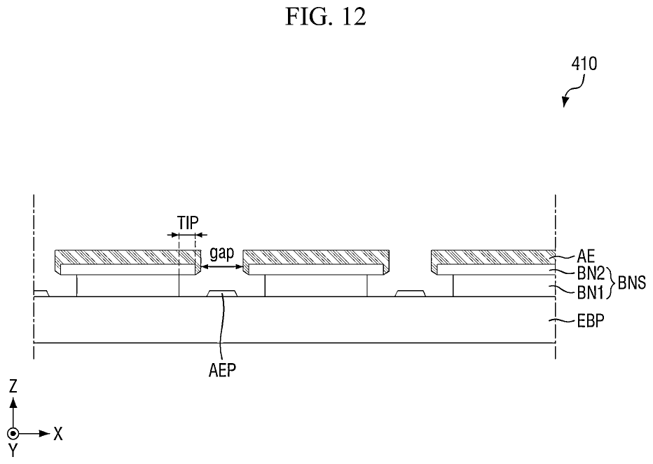

Next, referring to FIG. 12, a pixel electrode AE may be formed on the second bank layer BN2. The pixel electrode AE may be formed by a thermal evaporation.

Materials forming the pixel electrode AE according to an embodiment may be formed to be spaced apart on the bank structures BNS without a separate etching process since the second bank layer BN2 may include the tip TIP. For example, since the pixel electrode AE does not include a separate photolithography and etching processes, the gap between the pixel electrodes may be designed to be minimal, and accordingly, a high-resolution display device may be implemented.

Materials forming the pixel electrode AE may not only be positioned on the bank structure BNS but may also be positioned on the light emitting element backplane EBP in a portion not overlapping the bank structure BNS. The materials forming the pixel electrode AE positioned on the light emitting element backplane EBP may become the residual pattern AEP shown in FIG. 6. Accordingly, the residual pattern AEP and the pixel electrode AE may include a same material, and the residual pattern AEP and the pixel electrode AE may be spaced apart from each other.

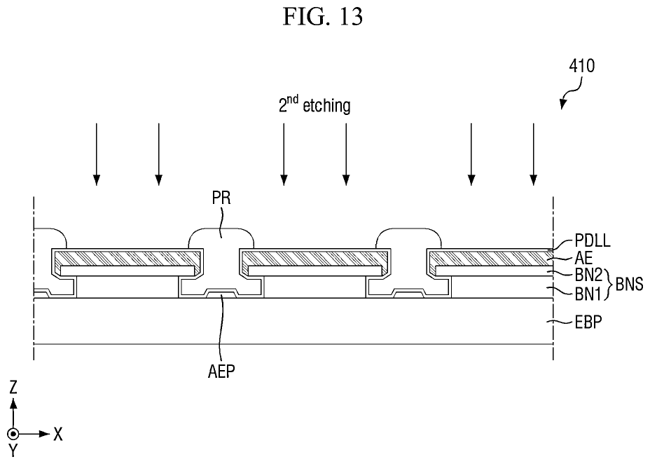

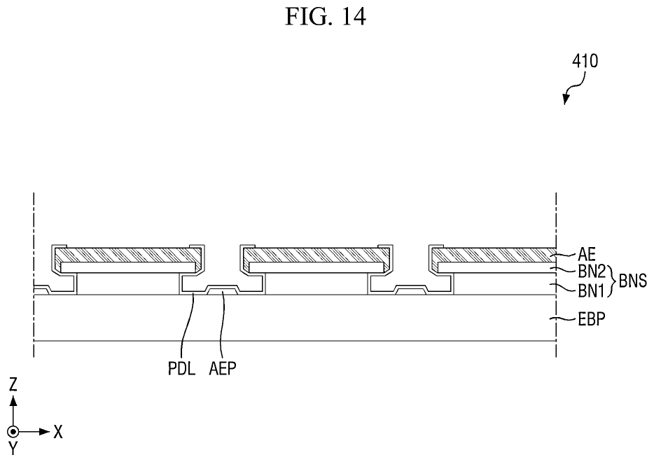

Next, referring to FIGS. 13 and 14, a pixel defining material layer PDLL may be formed over the entire pixel electrode AE and the residual pattern AEP. The pixel defining material layer PDLL may include an inorganic insulating material and may be formed in the same thickness according to the profile of the underlying structure.

Subsequently, multiple photoresist patterns PR may be formed on the pixel defining material layer PDLL in the portion overlapping the residual pattern AEP, and a second etching process (2^{nd} etching) may be performed using the photoresists PR as a mask.

In this process, the pixel defining material layer PDLL in the portion where the photoresist PR may not be formed may be removed, and the pixel defining material layer PDLL may become the pixel defining layer PDL shown in FIG. 6. The pixel defining layer PDL may be positioned to surround the edge of the pixel electrode AE and cover the residual pattern AEP.

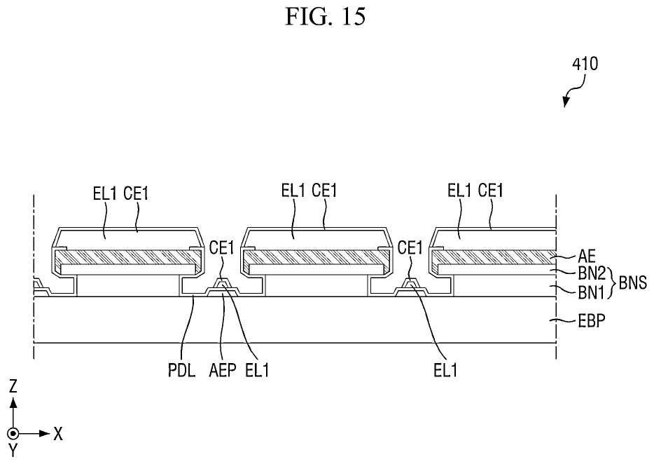

Next, referring to FIGS. 15 to 17, a first light emitting layer EL1 may be formed on the pixel electrode AE. The first light emitting layer EL1 according to an embodiment may be formed through a thermal evaporation process.

As the display panel 410 according to an embodiment may include a bank structure BNS with an undercut, the material forming the first light emitting layer EL1 may be formed on the pixel electrode AE without a separate fine metal mask. The material forming the first light emitting layer EL1 according to an embodiment may be positioned on all of the pixel electrodes AE and may also be positioned on the pixel defining layer PDL in the portion overlapping the residual pattern AEP. The material forming the first light emitting layer EL1 positioned on the residual pattern AEP and the material forming the first light emitting layer EL1 positioned on the pixel electrode AE may be spaced apart from each other.

Next, a first cathode electrode CE1 may be formed on the first light emitting layer EL1. The first cathode electrode CE1 according to an embodiment may be formed through a thermal evaporation process.

As the display panel 410 according to an embodiment may include a bank structure BNS with an undercut, the material forming the first cathode electrode CE1 may be formed on the first light emitting layer EL1 without a separate fine metal mask. The material forming the first cathode electrode CE1 according to an embodiment may be positioned on all of the first light emitting layers EL1 and may also be deposited on the material forming the first light emitting layer EL1 in the portion overlapping the residual pattern AEP. The material forming the first cathode electrode CE1 positioned on the residual pattern AEP and the material forming the first cathode electrode CE1 positioned on the pixel electrode AE may be spaced apart from each other.

The deposition process for forming the first cathode electrode CE1 according to an embodiment may be performed at an angle from the upper surface of the pixel electrode AE compared to the deposition process for forming the first light emitting layer EL1. For this reason, the deposition material forming the first cathode electrode CE1 may entirely cover the material forming the first light emitting layer EL1. For example, the step coverage of the deposition process for forming the first cathode electrode CE1 may be higher than the step coverage of the deposition process for forming the first light emitting layer EL1.

Subsequently, the first capping layer CCP1 may be formed on the first cathode electrode CE1. The first capping layer CCP1 according to an embodiment may be formed through a sputtering process.

As the display panel 410 according to an embodiment may include a bank structure BNS with an undercut, the material forming the first capping layer CCP1 may be formed on the first cathode electrode CE1 without a separate fine metal mask. The material forming the first capping layer CCP1 according to an embodiment may be positioned on all of the first cathode electrodes CE1, and may also be deposited on the material forming the first cathode electrodes CE1 in the portion overlapping the residual pattern AEP. The material forming the first capping layer CCP1 positioned on the residual pattern AEP and the material forming the first capping layer CCP1 positioned on the pixel electrode AE may be spaced apart from each other.

The sputtering deposition process for forming the first capping layer CCP1 according to an embodiment may have a higher step coverage than the thermal evaporation process for forming the first cathode electrode CE1. For this reason, the deposition material forming the first capping layer CCP1 may entirely cover the material forming the first cathode electrode CE1. The deposition material forming the first capping layer CCP1 may also cover a portion of the pixel defining layer PDL.

Through this process, a first light emitting element ED1 shown in FIG. 6 may be formed.

Next, a photoresist PR may be formed on the first capping layer CCP1 in a portion overlapping the first light emitting element ED1, and a third etching process (3^{rd} etching) may be performed using the photoresist PR as a mask.

In this process, the material forming the first light emitting layer EL1, the material forming the first cathode electrode CE1, and the material forming the first capping layer CCP1 in the portion where the photoresist PR may not be formed may be removed, and the pixel defining layer PDL and the pixel electrode AE that do not overlap the first light emitting element ED1 may be exposed.

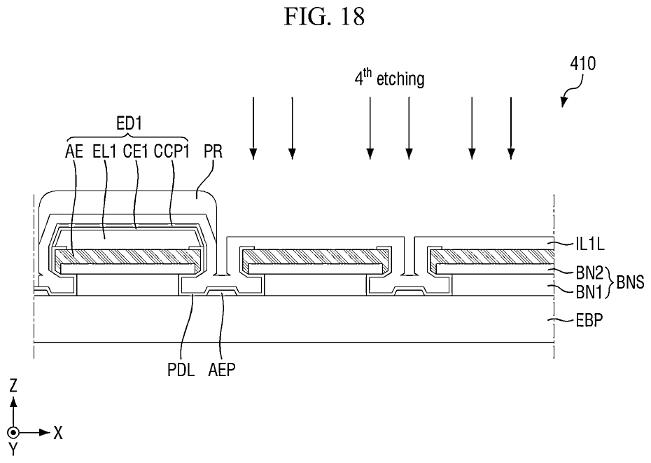

Next, referring to FIG. 18, a first inorganic material layer ILIL may be formed on the first light emitting element ED1. The first inorganic material layer ILIL may be formed by a chemical vapor deposition process (PECVD). The first inorganic material layer ILIL may be formed on the entire surface to be formed on a portion overlapping not only the first light emitting element ED1 but also the residual pattern AEP and the pixel electrodes AE. Subsequently, a photoresist PR may be formed on the first inorganic material layer ILIL in the portion overlapping the first light emitting element ED1, and then a fourth etching process (4th etching) may be performed using the photoresist PR as a mask. In this process, the portion of the first inorganic material layer ILIL where the photoresist PR may not be formed may be removed.

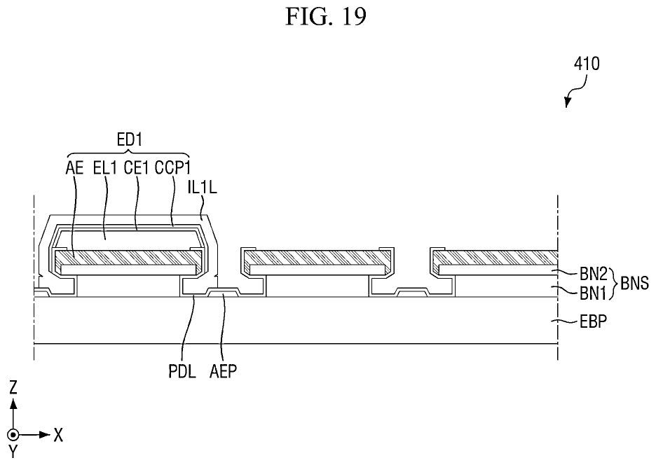

As shown in FIG. 19, the first inorganic material layer ILIL may entirely cover the first light emitting element ED1 and the bank structure BNS, and may also cover the undercut portion of the bank structure BNS. The pixel defining layer PDL and the pixel electrode AE overlapping the portion where the first inorganic material layer ILIL is not formed may be exposed.

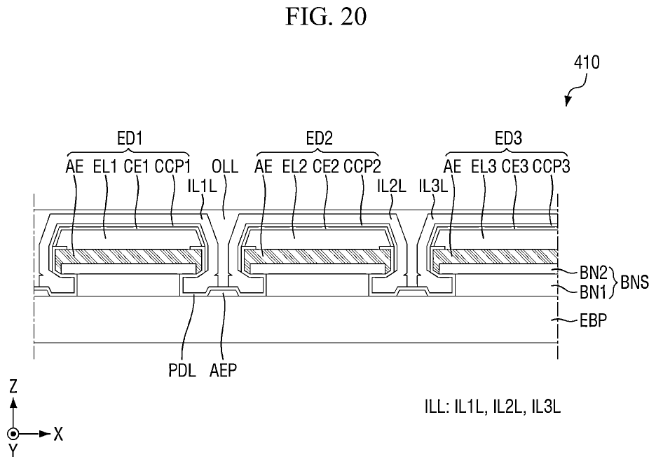

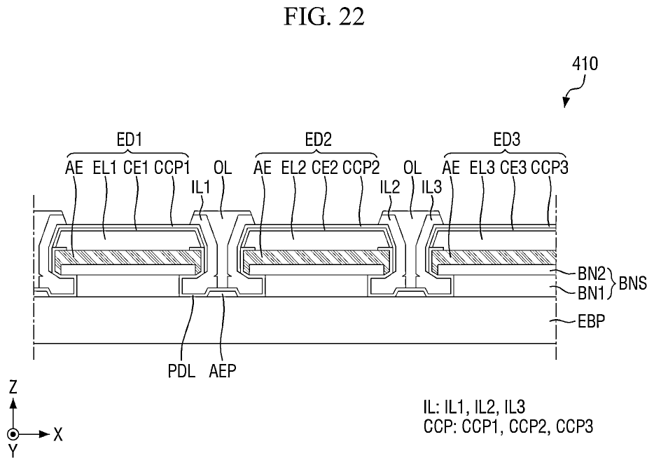

Referring to FIGS. 20 and 22, the process described above may be repeated to form a second light emitting element ED2 and a second inorganic material layer IL2L covering the second light emitting element ED2, and then a third light emitting element ED3 and a third inorganic material layer IL3L covering the third light emitting element ED3. Each of the first inorganic material layer ILIL, the second inorganic material layer IL2L, and the third inorganic material layer IL3L may be spaced apart in the first direction X, and the pixel defining layer PDL positioned between the first inorganic material layer ILIL, the second inorganic material layer IL2L, and the third inorganic material layer IL3L spaced apart from each other may be exposed.

Next, an organic material layer OLL may be formed on an inorganic material layer ILL. The organic material layer OLL may be formed on the entire surface, completely cover the inorganic material layer ILL, and planarize the step formed by the inorganic material layer ILL.

Subsequently, a photoresist PR may be formed on the organic material layer OLL in the area overlapping the residual pattern AEP, and a fifth etching process (5^{th} etching) may be performed using multiple photoresists PR as a mask. For example, the fifth etching process (5^{th} etching) may be performed as a dry etching process. Since the capping layer CCP according to embodiment has high etch resistance in a dry etching process, the fifth etching process (5^{th} etching) may be performed up to the portion exposing the capping layer CCP.

Through this process, the organic material layer OLL and the inorganic material layer ILL in the portion where the photoresist PR may not be formed may be removed to produce the inorganic layer IL and the organic layer OL shown in FIG. 6. A portion of the first capping layer CCP1, a portion of the second capping layer CCP2, and a portion of the third capping layer CCP3 may be exposed through this process. In other words, the first to third inorganic layers IL1, IL2, and IL3 may be positioned to surround the edge of each of the first to third capping layers CCP1, CCP2, and CCP3, respectively, and the organic layer OL may also be positioned to surround the edges of the first to third capping layers CCP1, CCP2, and CCP3.

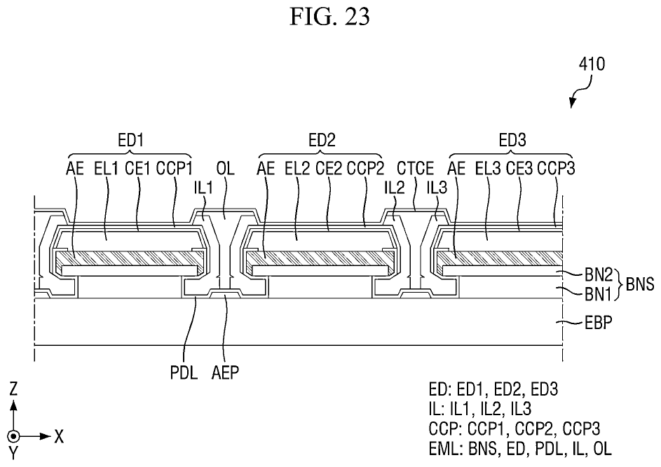

Finally, as shown in FIG. 23, a connection electrode CTCE may be deposited on the capping layer CCP, the inorganic layer IL, and the organic layer OL to form the light emitting element layer EML shown in FIG. 6.

The connection electrode CTCE may be formed through a sputtering deposition process and may be formed entirely on the capping layer CCP, the inorganic layer IL, and the organic layer OL. The connection electrode CTCE may be in contact with the capping layer CCP, the inorganic layer IL, and the organic layer OL, and the first to third capping layers CCP1, CCP2, and CCP3 may be electrically connected through the connection electrode CTCE.

As a result, the display panel 410 according to an embodiment may include a bank structure BNS with an undercut below the light emitting element ED, thereby allowing for the formation of multiple pixel electrodes AE without a separate etching process. By including an organic layer OL that planarizes the steps formed between the first to third inorganic layers IL1, IL2, and IL3, the connection electrode CTCE may be formed without disconnection defects. Accordingly, the first to third cathode electrodes CE1, CE2, and CE3 included in an embodiment may be electrically connected through the connection electrode CTCE.

Embodiments have been disclosed herein, and although terms may be employed, they may be used and may be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the following claims.

What is claimed is:

1. A display device comprising:
a substrate including an emission area and a non-emission area;
a bank structure positioned on the emission area of the substrate and having an undercut shape;
a pixel electrode positioned on the bank structure;
a first light emitting layer positioned on the pixel electrode;
a first cathode electrode positioned on the first light emitting layer;
a first capping layer positioned on the first cathode electrode;
a connection electrode positioned on the first capping layer;
a pixel defining layer positioned on the non-emission area of the substrate and defining a first opening;
an inorganic layer positioned on the pixel defining layer and defining a second opening; and
an organic layer positioned on the inorganic layer.

2. The display device of claim 1, wherein the bank structure comprises:
a first bank layer; and
a second bank layer positioned on the first bank layer and including a tip protruding toward the non-emission area more than a side surface of the first bank layer.

3. The display device of claim 2, wherein the first bank layer and the second bank layer include different inorganic insulating materials.

4. The display device of claim 3, wherein a height of the first bank layer in a vertical direction of the substrate is higher than a height of the second bank layer.

5. The display device of claim 3, wherein the side surface of the first bank layer is entirely covered by the pixel defining layer.

6. The display device of claim 3, wherein the second bank layer includes a first surface facing the pixel electrode, a second surface facing the first bank layer, and a side surface connecting the first surface and the second surface.

7. The display device of claim 6, wherein
the first surface and the side surface of the second bank layer are in contact with the pixel electrode, and
the second surface is in contact with the pixel defining layer.

8. The display device of claim 1, further comprising:
a residual pattern positioned in the non-emission area of the substrate, wherein
the residual pattern and the pixel electrode include a same material, and
the residual pattern is spaced apart from the pixel electrode.

9. The display device of claim 8,
wherein the pixel defining layer entirely covers the residual pattern.

10. The display device of claim 1, further comprising
a second light emitting layer spaced apart from the first light emitting layer in a direction parallel to the substrate with the organic layer disposed between the first light emitting layer and the second light emitting layer;
a second cathode electrode positioned on the second light emitting layer; and
a second capping layer positioned on the second cathode electrode,
wherein the first cathode electrode and the second cathode electrode are spaced apart from each other and the first capping layer and the second capping layer are spaced apart from each other.

11. The display device of claim 10, wherein
the first capping layer is electrically connected to the first cathode electrode, and
the second capping layer is electrically connected to the second cathode electrode.

12. The display device of claim 11, wherein the connection electrode comprises:
a first portion in contact with the first capping layer;
a second portion in contact with the second capping layer; and
a third portion in contact with the organic layer.

13. The display device of claim 12, wherein the first portion and the second portion are spaced apart from each other with the third portion disposed between the first portion and the second portion.

14. The display device of claim 10, wherein the inorganic layer comprises:
a first inorganic layer surrounding an edge of the first capping layer; and
a second inorganic layer surrounding an edge of the second capping layer,
wherein the first inorganic layer and the second inorganic layer are spaced apart from each other with the organic layer disposed between the first inorganic layer and the second inorganic layer.

15. The display device of claim 1, wherein in plan view, the first opening is entirely surrounded by the second opening.

16. A method of manufacturing a display device, the method comprising:
forming a first bank layer on a substrate and forming a second bank layer on the first bank layer;
etching a portion of the first bank layer and a portion of the second bank layer so that the second bank layer includes a tip protruding more than a side surface of the first bank layer;
forming a pixel electrode on the second bank layer and a residual pattern on the substrate;
forming a pixel defining layer surrounding an edge of the pixel electrode and covering the residual pattern;
forming a light emitting layer, a cathode electrode, and a capping layer on the pixel electrode; and
forming a connection electrode on the capping layer.

17. The method of claim 16, wherein in forming the pixel electrode, the pixel electrode does not include a separate etching process since the second bank layer includes a tip.

18. The method of claim 17, wherein in the forming the cathode electrode and the capping layer, the cathode electrode entirely covers the light emitting layer, and the capping layer entirely covers the cathode electrode.

19. The method of claim 18, further comprising:
forming an inorganic layer and an organic layer after the forming of the capping layer and before the forming of the connection electrode,
wherein in forming the inorganic layer, the inorganic layer surrounds an edge of the capping layer and covers a portion of the residual pattern.

20. The method of claim 19, wherein,
in the forming the connection electrode, the connection electrode is extended to the capping layer, the inorganic layer, and the organic layer, and
the cathode electrode is electrically connected to the connection electrode through the capping layer.
